(19) United States
(12) Patent Application Publication
(10) Pub. No.: US 2018/0059656 A1
(43) Pub. Date: Mar. 1, 2018

(54) Machine Diagnostic Device and Machine Diagnostic Method

(71) Applicant: Hitachi, Ltd., Chiyoda-ku, Tokyo (JP)

(72) Inventors: Tomoaki HIRUTA, Tokyo (JP); Kohji MAKI, Tokyo (JP); Tetsuji KATO, Tokyo (JP); Yoshitaka ATARASHI, Tokyo (JP)

(73) Assignee: Hitachi, Ltd., Chiyoda-ku, Tokyo (JP)

(21) Appl. No.: 15/557,242

(22) PCT Filed: Mar. 12, 2015
(86) PCT No.: PCT/JP2015/057301

§ 371 Date: Sep. 11, 2017

(51) Int. Cl. G05B 23/02; G06F 15/18

(52) U.S. Cl. CPC G05B 23/0243; G01R 31/00; G05B 23/0283; G06F 15/18

(57) ABSTRACT

The purpose of the present invention is to provide a machine diagnostic device that assists with sensor attachment such that malfunction sensing performance may be maintained even after maintenance of a device. The machine diagnostic device includes a sensor data acquisition part that acquires time-series sensor data that are measured by sensors that are attached to a machine that has one or more operating modes; a learning unit that statistically processes the sensor data prior to detachment of the sensors and computes a normal operation model; a malfunction diagnostic unit that diagnoses a malfunction of the machine on the basis of the sensor data and the normal operation model; and a sensor adjustment unit that, when the sensors are re-attached to the machine after the sensors have been detached therefrom, displays, in a display unit, as a sensor adjustment mode, discrepancies between the normal operation model prior to the detachment of the sensors and the post sensor attachment sensor data.

### TECHNICAL FIELD

The present invention relates to a machine diagnostic device that diagnoses abnormality of a machine, and a machine diagnostic method.

### BACKGROUND ART

Machines such as a power generation gas turbine for social infrastructure are demanded to operate for 24 hours a day. It is necessary to prevent unexpected operation stoppage to maintain high operation rate of the machines. To prevent the unexpected operation stoppage, it is necessary to switch a maintenance method from periodic maintenance of the related art based on machine operation time into state monitoring maintenance of appropriately performing preventive maintenance on the basis of a machine state.

To realize the state monitoring maintenance, it is important for a machine diagnostic device to play a role of analyzing sensor data that is collected through various sensors provided to a machine according to an abnormality diagnostic procedure that is determined, and of diagnosing abnormality of the machine and indication of a failure. Here, an abnormality diagnostic procedure represents a processing flow of a computer that processes data acquired from one or more sensors, and diagnoses an indication of abnormality of the machine and the like on the basis of the resultant processing result.

Typically, in a case where the abnormality of the machine is diagnosed in the state monitoring maintenance, an engineer stops the machine in periodic maintenance such as an overhaul. In addition, when the maintenance is performed in a large scale, sensors of the machine are separated once, and component exchange and maintenance of an inner side of the machine are performed. Then, the sensors are returned to the original positions, and the state monitoring maintenance continues. The state monitoring maintenance diagnoses the abnormality of the machine on the basis of a normal state of the machine. Therefore, when it does not return to a sensor state before the maintenance, it is difficult to achieve accurate state monitoring maintenance.

In inventions related to machine sensor attaching method of the related art, consideration is given to an accurate sensor attaching method. For example, as a sensor adjusting method, PTL 1 discloses the following configuration. An operator, who confirms a minimum lift position on a screen of a diagnostic device, compares a sensor output at that time and a standard output value to determine whether or not a deviation exists in an attaching angle (attaching position) (step S5). In a case where the deviation exists, the operator manually adjusts the attaching angle (attaching position) so that the sensor output pertains to a predetermined range (permissible range) including the standard output value (step S6).

### CITATION LIST

### Patent Literature

PTL 1: JP 2008-196420 A

### SUMMARY OF INVENTION

### Technical Problem

PTL 1 relates to a technology of comparing an output value of a sensor with a standard output value that is set with design information to determine a sensor position. In a case where this technology is executed after sensor attachment after the state monitoring maintenance, there is no guarantee that the output value of the sensor before the maintenance and the standard output value are in the same level. In addition, typically, a machine that is an object of the state monitoring maintenance has various operation modes. In addition, typically, a sensor value obtained from the sensor, which is provided to the machine, is different for each operation mode. Therefore, it is difficult to reproduce a state of the machine before the maintenance with only the standard output value that is set with the design information.

As described above, in the case of applying the sensor adjusting method of the related art to the state monitoring maintenance, there is a problem that it is difficult to reproduce the state of the machine before the maintenance, and abnormality diagnostic performance deteriorates.

The invention has been made to solve the above-described problem, and an object thereof is to provide a machine diagnostic device that assists with sensor attachment so as to maintain abnormality sensing performance even after maintenance of a machine, and a machine diagnostic method.

### Solution to Problem

In order to achieve the object, a machine diagnostic device according to the present invention includes: a sensor data acquiring unit that acquires time-series sensor data that is measured by a sensor attached to a machine having one or more operation modes; a learning unit that calculates a normal operation model through statistical processing of the sensor data before detachment of the sensor; an abnormality diagnostic unit that diagnoses abnormality of the machine on the basis of the sensor data and the normal operation model; and a sensor adjusting unit that displays an error between a normal operation model before detachment of the sensor and sensor data after attachment of the sensor on a display unit as a sensor adjustment mode when the sensor is attached again to the machine after detachment of the sensor. Another aspect of the invention will be described in embodiments to be described later.

### Advantageous Effects of Invention

According to the invention, it is possible to assist attachment of a sensor so as to maintain abnormality sensing performance even after maintenance of a machine.

### BRIEF DESCRIPTION OF DRAWINGS

FIG. 1 is a view illustrating an example of behaviors performed by a machine, a machine diagnostic device, a maintenance person, and a manager.

FIG. 2 is a view illustrating an example of a block configuration of a machine diagnostic device according to Embodiment 1.

FIG. 3 is a view illustrating an example of a configuration of a sensor parameter.

FIG. 4 is a view illustrating an example of a configuration of sensor data.

FIG. 5 is a view illustrating an example of a configuration of operation mode data.

FIGS. 6A to 6C are views illustrating an example of a current waveform in each operation mode in a case where a machine is an electric motor, and FIG. 6A is an example of a current waveform of an activation operation mode, FIG. 6B is an example of a current waveform of a normal operation mode, and FIG. 6C is an example of a current waveform of an acceleration operation mode.

FIG. 7 is a flowchart illustrating an example of an operation mode specifying process that is executed by an operation mode specifying unit.

FIG. 8 is a view illustrating an example of a configuration of a normal operation model.

FIG. 9 is a view illustrating an example of a configuration of diagnostic procedure information.

FIG. 10 is a flowchart illustrating an example of an abnormality diagnostic process that is executed by an abnormality diagnostic unit.

FIG. 11 is a flowchart illustrating an example of a learning process that is executed by a learning unit.

FIG. 12 is a flowchart illustrating an adjusting process of a sensor adjusting unit according to Embodiment 1.

FIG. 13 is a view illustrating an example of a sensor adjusting screen of the sensor adjusting unit.

FIG. 14 is a flowchart illustrating an adjusting process of a sensor adjusting unit according to Embodiment 2.

FIG. 15 is a flowchart illustrating an adjusting process of a sensor adjusting unit according to Embodiment 3.

FIG. 16 is a flowchart illustrating an adjusting process of a sensor adjusting unit according to Embodiment 4.

FIG. 17 is a view illustrating an example of calculation of the degree of abnormality by using cluster analysis.

### DESCRIPTION OF EMBODIMENTS

Hereinafter, embodiments of the invention will be described in detail with reference to the accompanying drawings.

### Embodiment 1

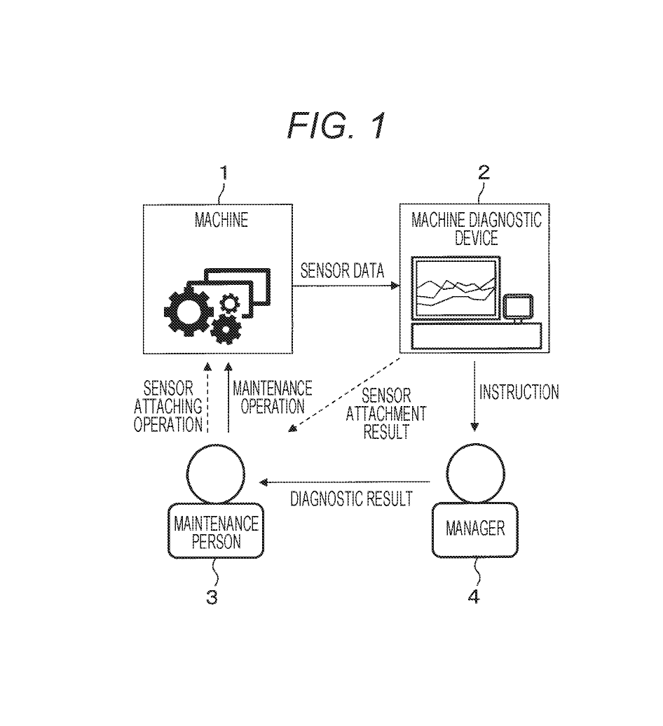

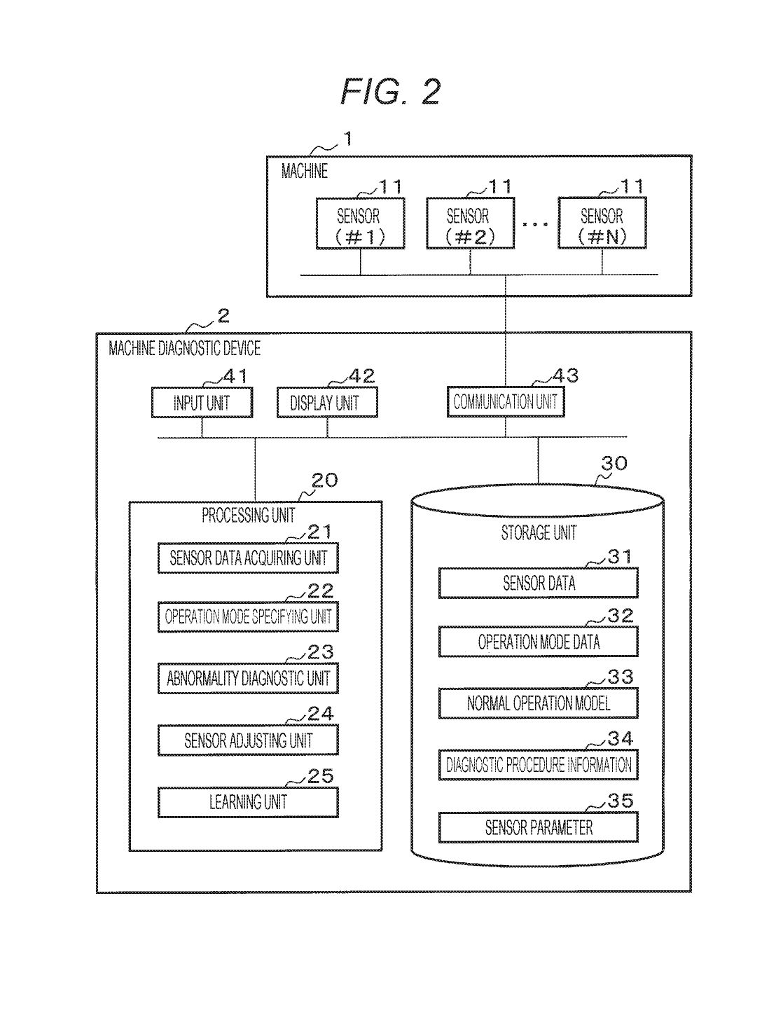

FIG. 1 is a view illustrating an example of behaviors performed by a machine 1, a machine diagnostic device 2, a maintenance person 3, and a manager 4. The machine 1 is an object device to be monitored by the machine diagnostic device 2. Maintenance of the machine 1 is periodically performed, or in a case where the machine diagnostic device 2 detects abnormality or indication of the abnormality (hereinafter, simply referred to “abnormality”), maintenance by the maintenance person 3 is performed. Various sensors 11 (refer to FIG. 2) are mounted on the machine 1, and various pieces of measurement data, which are measured by the various sensors 11, of the machine 1 are output to the machine diagnostic device 2.

The machine diagnostic device 2 collects and accumulates the various pieces of measurement data measured by the various sensors 11 from the machine 1, periodically diagnoses presence or absence of abnormality of the machine 1 in accordance with a predetermined abnormality diagnostic procedure, and notifies the manager 4 of the diagnostic result. When grasping the abnormality of the machine 1 or a cause of the abnormality (contents of a failure) on the basis of the notification of the diagnostic result from the machine diagnostic device 2, the manager 4 gives an instruction for the maintenance person 3 in place to perform a maintenance operation on the machine 1. In addition, when attaching each of the sensors 11 after the maintenance of the machine, the maintenance person attaches the sensor 11 by using information that is displayed on the machine diagnostic device 2.

FIG. 2 is a view illustrating an example of a block configuration of the machine diagnostic device 2 according to Embodiment 1. As illustrated in FIG. 2, the machine diagnostic device 2 includes a processing unit 20, a storage unit 30, an input unit 41, a display unit 42, and a communication unit 43. The processing unit 20 includes a sensor data acquiring unit 21, an operation mode specifying unit 22, a learning unit 25, an abnormality diagnostic unit 23, and a sensor adjusting unit 24.

The sensor data acquiring unit 21 acquires time-series sensor data 31, which is measured, from the sensor 11 attached to the machine 1 having one or more operation modes. The operation mode specifying unit 22 specifies an operation mode from the sensor data 31.

The learning unit 25 calculates a normal operation model 33 through statistical processing of the sensor data 31 before detachment of the sensor 11. The abnormality diagnostic unit 23 diagnoses abnormality of the machine at a predetermined interval by using the sensor data 31 and the normal operation model 33.

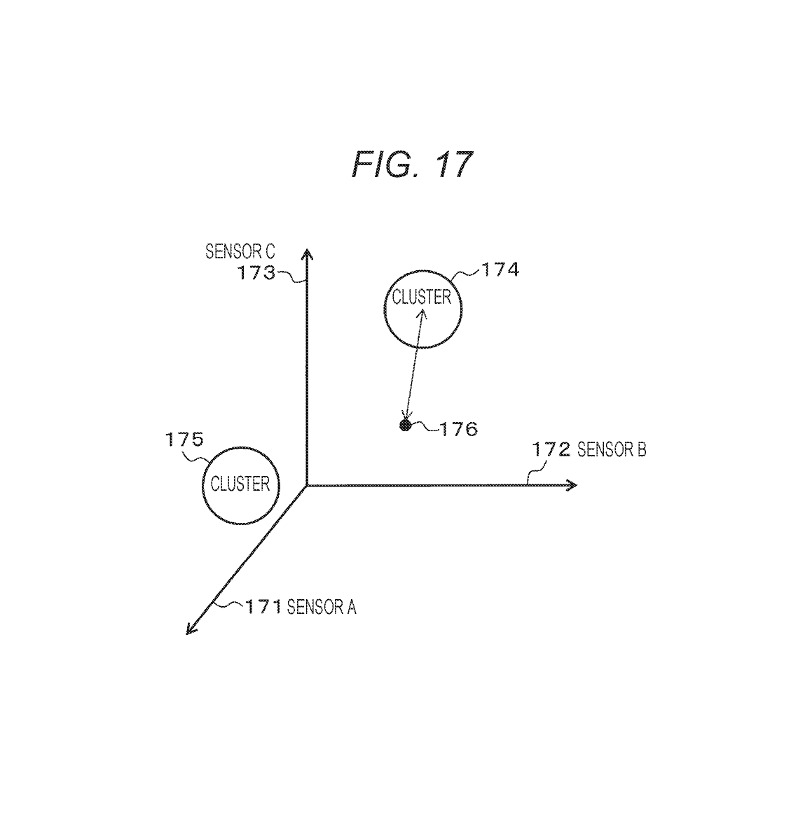

As a sensor adjustment mode when attaching the sensor 11 to the machine 1 again after detaching the sensor 11 and performing maintenance of the machine 1, the sensor adjusting unit 24 displays a degree of abnormality (error) between the normal operation model before detachment and the sensor data after sensor attachment on the display unit 42. Furthermore, the degree of abnormality will be described later with reference to FIG. 17.

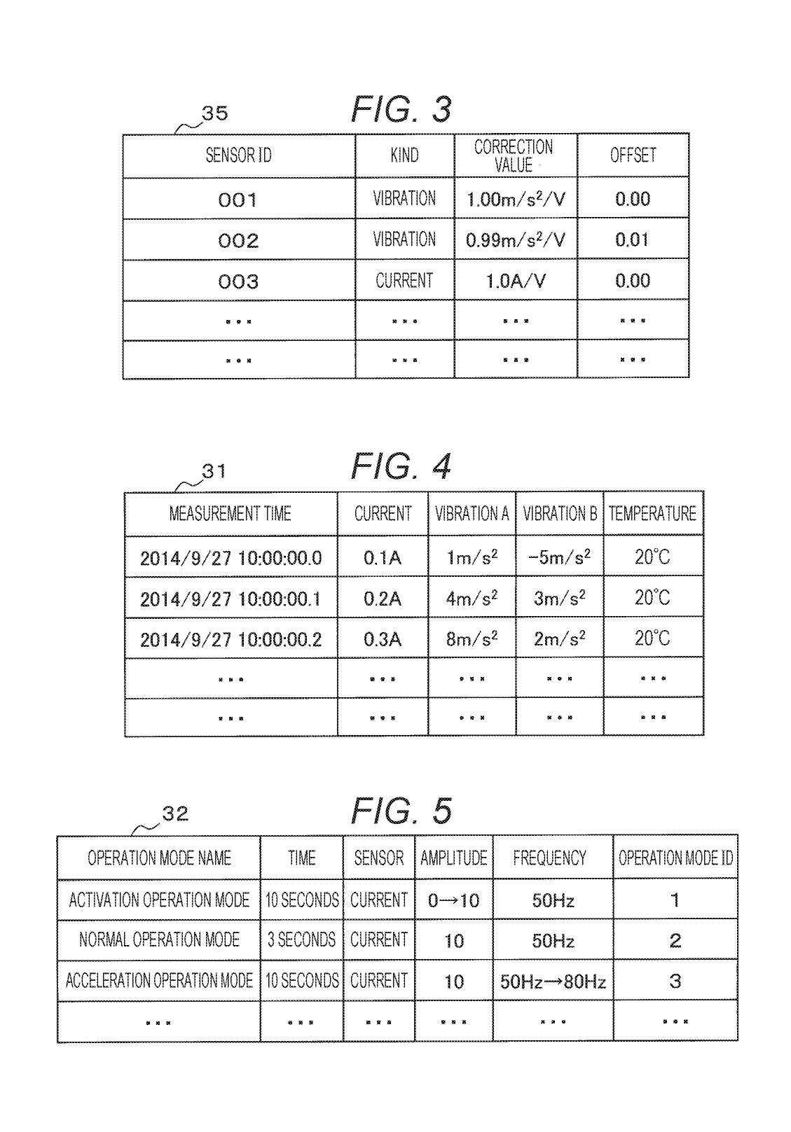

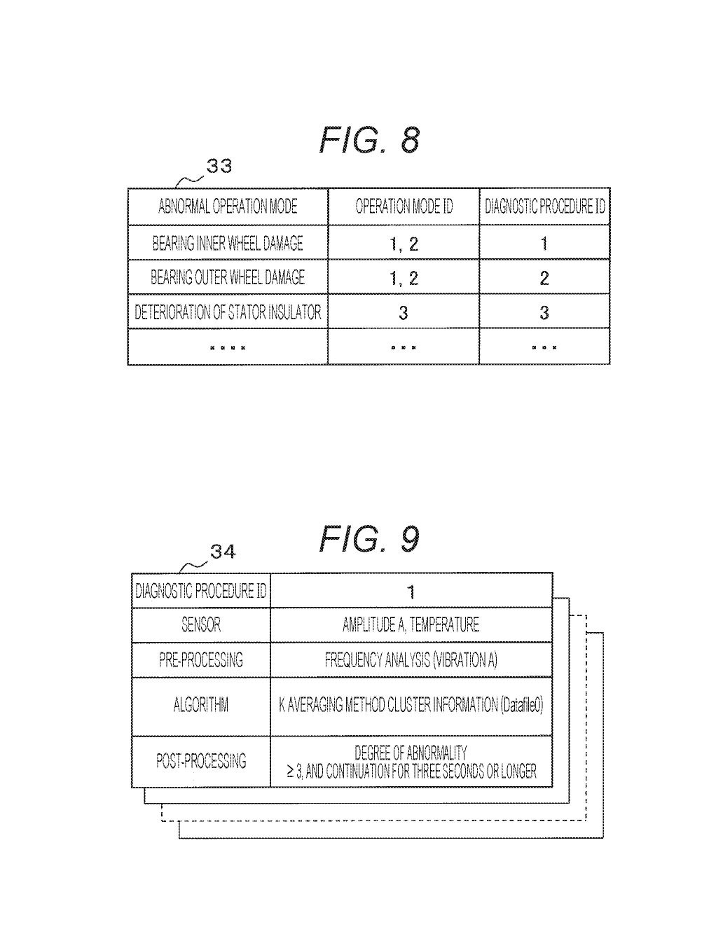

The storage unit 30 stores the sensor data 31 (refer to FIG. 4) acquired by the sensor data acquiring unit 21, the operation mode data 32 (refer to FIG. 5), the normal operation model 33 (refer to FIG. 8) that is generated through mechanical learning in the learning unit 25, a diagnostic procedure information 34 (refer to FIG. 9), a sensor parameter 35 (refer to FIG. 3), and the like.

Here, for example, the processing unit 20 is an operation processing device such as a microprocessor, and the storage unit 30 is a storage device such as a semiconductor memory and a hard disk drive. The input unit 41 is an input device such as a keyboard and a mouse, and the display unit 42 is a display device such as a liquid crystal device. Each function of the sensor data acquiring unit 21, the operation mode specifying unit 22, the abnormality diagnostic unit 23, the sensor adjusting unit 24, and the learning unit 25 is realized when the operation processing device executes a predetermined program stored in the storage device.

Furthermore, in this embodiment, the machine 1 that is an object to be diagnosed by the machine diagnostic device 2 may be any apparatus as long as the apparatus performs a predetermined function through a mechanical operation. However, in this embodiment, for example, the machine 1 is set as an electric motor, or an apparatus including the electric motor and a mechanical section that is driven by the electric motor for easy comprehension of the contents of the invention. The electric motor is a master component that is mounted in a various production facilities, and converts electric energy into mechanical energy.

One or more sensors 11 are attached to the machine 1 to monitor an operation state. In a case where the machine 1 is an electric motor, for example, a current sensor that measures a current input to the electric motor, one or more vibration sensors which measure vibration of a bearing and the like of the electric motor, a temperature sensor that measures an ambient temperature of the bearing, and the like are attached to the machine 1. The sensors 11 measure the current, the vibration, the temperature, and the like at a time interval that is determined in advance, and supply measured data to the machine diagnostic device 2 as measurement data.

Hereinafter, respective blocks, which constitute the machine diagnostic device 2, will be described in detail with reference to drawings after FIG. 3 in addition to FIG. 2.

### Acquisition of Sensor Data

The sensor data acquiring unit 21 (refer to FIG. 2) acquires sensor data from the sensors 11 attached to the machine 1 through the communication unit 43 in a wired manner or a wireless manner. In addition, the sensor data acquiring unit 21 converts a voltage, which is supplied from the sensors 11, into physical quantities such as a current, a temperature, and an acceleration by using the sensor parameter 35 stored in the storage unit 30, and stores the result in the storage unit 30 as measurement data (sensor data 31).

FIG. 3 is a view illustrating an example of a configuration of the sensor parameter 35. As illustrated in FIG. 3, the sensor parameter 35 is constituted by “sensor ID” that is an identification ID of each of the sensors 11 attached to the machine 1, “kind” of the sensors 11, “correction value” for conversion of the voltage, which is measured by the sensors 11, into a physical use, and “offset”. For example, in FIG. 3, a vibration sensor having a sensor ID of 001 is a sensor that measures vibration of 1.00 m/s² per a sensor output value of 1 V. In addition, in a case where a bias is present in the output voltage, an item of the offset is added to the output value.

FIG. 4 is a view illustrating an example of a configuration of the sensor data 31. As illustrated in FIG. 4, the sensor data 31 is constituted by correlating the measurement data, which is measured by the sensors 11 attached to the machine 1, to measurement time.

In an example of the sensor data 31 in FIG. 4, for example, measurement data included in the sensor data 31 is set as a current, an acceleration, and a temperature which are respectively measured by a current sensor, two vibration sensors, and a thermometer which are attached to the electric motor. In addition, in this example, the entirety of a plurality of pieces of measurement data are measured in a cycle of 0.1 seconds, but measurement cycles of the plurality of pieces of measurement data may be different from each other. For example, the current may be measured at a cycle of 0.1 seconds, the vibration may be measured at a cycle of 0.01 seconds, and the temperature may be measured at a cycle of 1 second.

In addition, the cycle of measuring the measurement data by each of the sensors 11 may be different from a cycle of transmitting the measurement data from the sensor 11 to the sensor data acquiring unit 21. For example, the sensor 11 may measure the measurement data at an interval of 0.1 seconds, and may collect the measurement data corresponding to one second and supply the measurement data to the sensor data acquiring unit 21 at an interval of one second.

### Definition and Specifying of Operation Mode

FIG. 5 is a view illustrating an example of a configuration of the operation mode data 32. As illustrated in FIG. 5, the operation mode data 32 is constituted by data of items such as “name of an operation mode”, “time”, “sensor”, “amplitude”, “frequency”, and “operation mode ID”. Here, the “operation mode name” is a name for identifying an operation mode in an operation of the machine 1, the “time” is a period necessary to specify the operation mode, the “sensor” is a name of measurement data that is used to specify the operation mode, the “amplitude” is an amplitude of the measurement data or a variation amount of an amplitude value, the “frequency” is a frequency of the measurement data or a variation amount of the frequency, and the “operation mode ID” is a number or a symbol for identifying the operation mode.

The operation mode data 32 is data for defining the operation mode of the machine 1, and is created by the manager 4 in advance. The operation mode data 32 is used by the operation mode specifying unit 22 to confirm that the measurement data acquired by the sensor data acquiring unit 21 pertains to which operation mode.

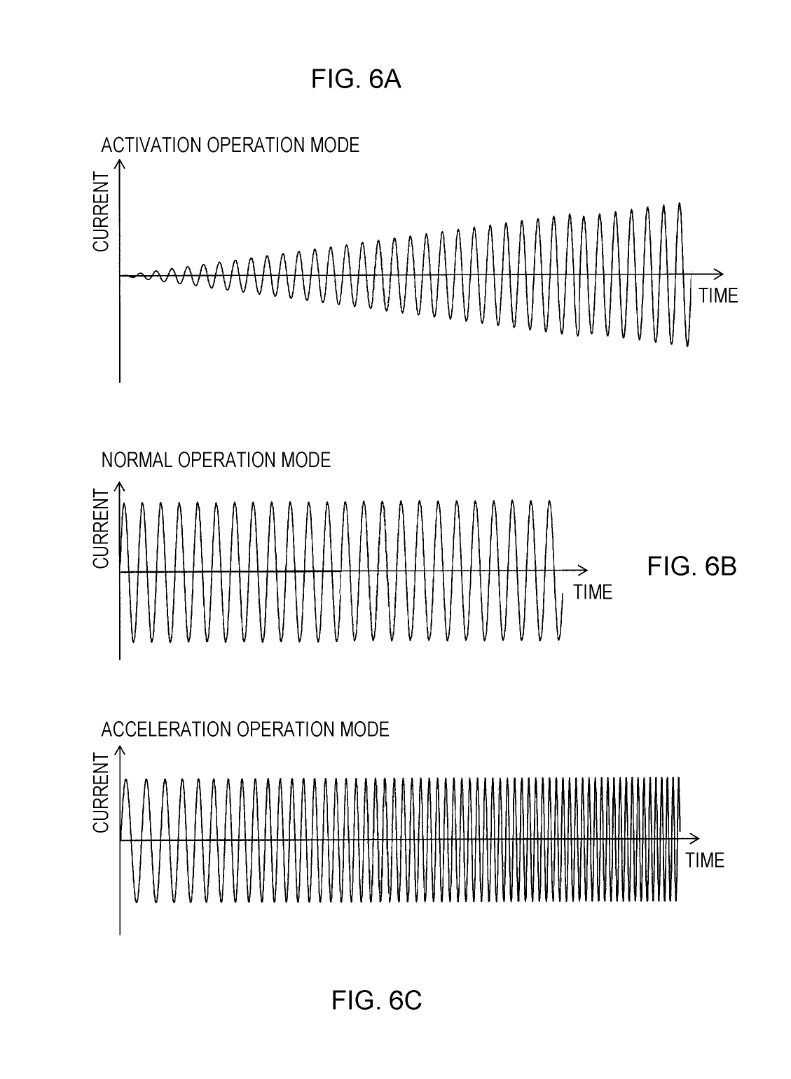

FIGS. 6(a) to 6(c) are views illustrating an example of a current waveform in each operation mode in a case where the machine 1 is an electric motor. FIG. 6(a) is an example of a current waveform of an activation operation mode, FIG. 6(b) is an example of a current waveform of a normal operation mode, and FIG. 6(c) is an example of a current waveform of an acceleration operation mode.

In the example in FIGS. 6(a) to 6(c), it is assumed that the operation mode is specified by the measurement data of a current in the machine 1 (electric motor). In addition, for example, when an amplitude of a current of a frequency of 50 Hz is raised from 0 A to 10 A for 10 seconds, an operation mode thereof is defined as the “activation operation mode”. In addition, in a case where a current of a frequency of 50 Hz maintains a constant amplitude of 10 A for three seconds, an operation mode thereof is defined as the “normal operation mode”. In addition, in a case where a frequency of a current having a constant amplitude of 10 A is changed from 50 Hz to 80 Hz for 10 seconds, an operation mode thereof is defined as the “acceleration operation mode”.

As illustrated in FIG. 6(a), a frequency of a current in the activation operation mode is approximately constant, but an amplitude of the current gradually increases from 0 A to a predetermined current value (for example, 10 A). In addition, as illustrated in FIG. 6(b), in the normal operation mode, with regard to measurement values of the current, the amplitude and the frequency becomes constant values. This represents a state in which the electric motor normally operates at a constant number of revolutions. In addition, as illustrated in FIG. 6(c), in the acceleration operation mode, the amplitude of the current is constant, but the frequency gradually increases, for example, from 50 Hz to 80 Hz. This represents a state in which the number of revolutions of the electric motor gradually increases.

Furthermore, the operation mode can be appropriately defined in addition to the operation modes illustrated in FIG. 5 and FIGS. 6(a) to 6(c). In a case where the machine 1 is the electric motor, a deceleration operation mode and a stopping operation mode may be further provided. In addition, as the normal operation mode, second and third operation modes, which are different in a frequency and an amplitude, may be provided.

In addition, the operation mode may be defined in combination of various pieces of measurement data. For example, in addition to the current input to the machine 1, a low-temperature starting operation mode that uses an ambient temperature of the machine 1, a booting operation mode at normal temperature, and the like may be defined. However, in measurement data in which variation time of a temperature and the like is very long, it is assumed that the “amplitude” in the operation mode data 32 in FIG. 4 is measurement data itself (temperature and the like). In addition, it is assumed that the “frequency” is simply constant without determining a particular value.

Hereinbefore, the example of the operation modes illustrated in FIG. 5 and FIGS. 6(a) to 6(c) is a simple example, but definition of the operation modes is not always permitted to everyone. Particularly, in a case where control specifications of the machine 1 are intended not to be disclosed, it is difficult to appropriately define the operation modes if an operator is not an expert familiar with a motion and an operation of the machine 1. Accordingly, in the machine diagnostic device 2 according to this embodiment, it is necessary for an expert to define the operation modes in advance.

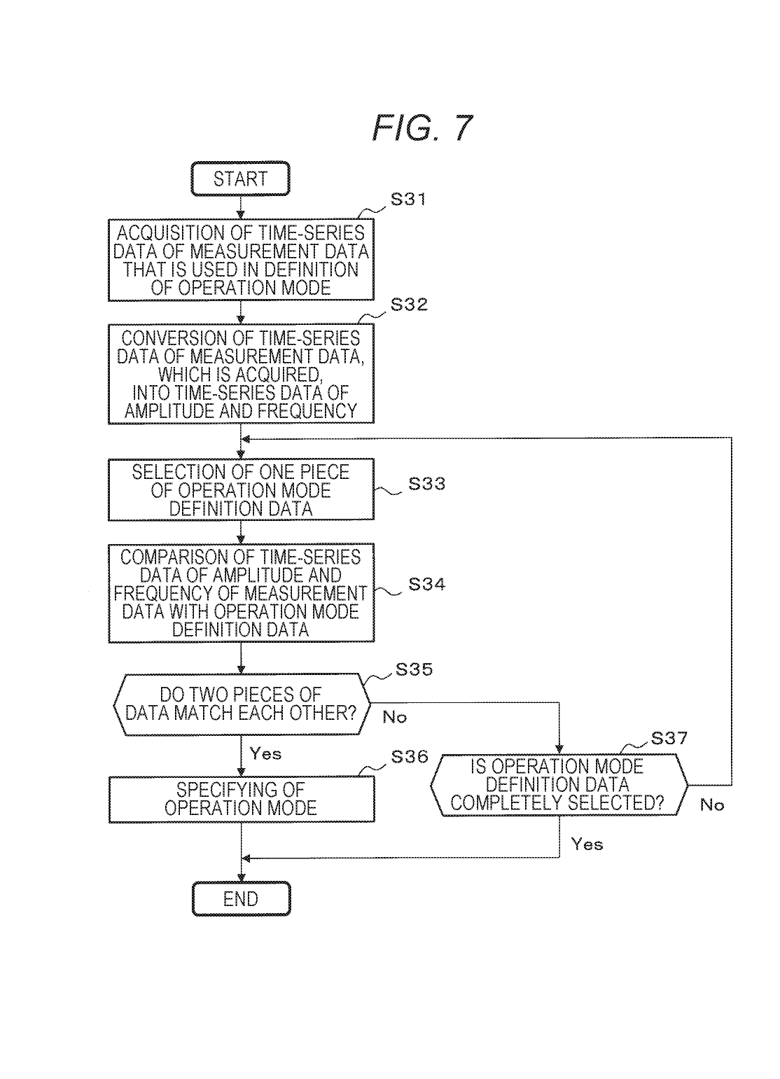

FIG. 7 is a flowchart illustrating an example of operation mode specifying process that is executed by the operation mode specifying unit 22. As illustrated in FIG. 7, first, the operation mode specifying unit 22 acquires time-series data of measurement data that is used in definition of the operation mode as the operation mode data 32 among a plurality of pieces of the sensor data 31 (refer to FIG. 4) which are input through the sensor data acquiring unit 21 (step S31).

Next, the operation mode specifying unit 22 converts the time-series data of the measurement data, which is acquired, into time-series data of “amplitude” and “frequency” (step S32). Furthermore, the “amplitude” stated here may be the time-series data itself of the measurement data in a case where a variation period is very greater than an acquisition cycle (sampling cycle) of the measurement data, and in this case, conversion into the “amplitude” is not necessary.

Next, the operation mode specifying unit 22 refers to a plurality of pieces of the operation mode data 32 which are stored in the storage unit 30, and selects one piece of operation mode definition data among the plurality of pieces of operation mode data 32 (step S33).

Next, the operation mode specifying unit 22 compares the time-series data of the “amplitude” and the “frequency” of the measurement data, which is obtained in step S32, with the operation mode definition data that is selected in step S33, more specifically, data (refer to FIG. 4) in columns of “amplitude”, “frequency”, and “time” of the operation mode data 32 (step S34). In addition, from the comparison result, in a case where the two pieces of data match each other (Yes in step S35), the operation mode specifying unit 22 specifies that an operation mode, to which the sensor data 31 corresponding to a matching time portion pertains, is the operation mode selected in step S33 (Step S36). As a result, the operation mode ID is acquired, and thus the process in FIG. 7 is terminated. In addition, the operation mode ID acquired as described above is supplied to the abnormality diagnostic unit 23.

On the other hand, from the comparison result in step S34, in a case where the two pieces of data do not match each other (No in step S35), the operation mode specifying unit 22 further determines whether or not the operation mode definition data is completely selected in the determination in step S33 (step S37). From the determination result, in a case where the operation mode definition data is not completely selected yet (No in step S37), it returns to step S33, and the processes from step S33 are repetitively executed.

In addition, in a case where it is determined that the operation mode definition data is completely selected in the determination in step S37 (Yes in step S37), the operation mode specifying unit 22 does not specify the operation mode, and terminates the process in FIG. 7. Accordingly, in this case, the operation mode ID is not searched, and thus the subsequent process in the abnormality diagnostic unit 23 is not performed.

Hereinbefore, the process illustrated with reference to FIG. 7 is a procedure of searching whether or not the sensor data 31, which is sequentially acquired in a predetermined time cycle, matches one of a plurality of pieces of the definition data of respective operation modes in the operation mode data 32.

### Abnormality Diagnosis of Machine 1

When receiving the operation mode ID from the operation mode specifying unit 22, the abnormality diagnostic unit 23 (refer to FIG. 2) performs abnormality diagnosis of the machine 1. Hereinafter, the abnormality diagnosis to be performed by the abnormality diagnostic unit 23 will be described in detail with reference to FIGS. 8 to 10.

FIG. 8 is a view illustrating an example of a configuration of the normal operation model 33. As illustrated in FIG. 8, the normal operation model 33 is a model that is generated through statistical processing of sensor data before detachment of a sensor, and “failure mode” is defined in the normal operation model 33. The “operation mode ID” and “diagnostic procedure ID” are correlated to each “failure mode”.

Here, specifically, the normal operation model 33 is generated in the learning unit 25 through mechanical learning of the sensor data in the machine 1. A normal operation model is information that defines a normal state of the machine for each operation mode. The abnormality diagnostic unit 23 determines abnormality of the machine using a distance with the normal operation model. In addition, the “operation mode ID” is information indicating an operation mode in which the “failure mode” may occur. In addition, the “diagnostic procedure ID” is information that identifies diagnostic procedure information for detection of the “failure mode”.

As can be seem from the example of the normal operation model 33 in FIG. 8, when the failure mode is “bearing inner wheel damage”, and the operation mode ID is “1” or “2”, abnormality diagnosis is performed by a diagnostic procedure in which the “diagnostic procedure ID” is set to “1”. Furthermore, in this embodiment, the above-described normal operation model 33 is data that is generated by the learning unit 25 in a state in which the sensor data of the machine 1 is accumulated. The “failure mode” is not limited to the example in FIG. 9.

FIG. 9 is a view illustrating an example of a configuration of the diagnostic procedure information 34. As illustrated in FIG. 9, the diagnostic procedure information 34 includes information such as “diagnostic procedure ID”, “sensor”, “pre-processing”, “algorithm”, and “post-processing”.

Here, the “diagnostic procedure ID” is information for identification of the diagnostic procedure information 34. In addition, the “sensor” is a name of measurement data that is used in the diagnostic procedure. The example in FIG. 9 illustrates a case where “vibration A” and “temperature” are used in the diagnostic procedure.

The “pre-processing” is information that designates processing performed with respect to measurement data that is designated by the “sensor” during application of the diagnostic algorithm. Examples of the “pre-processing” include filtering processing for removing a noise, movement averaging processing, and the like. In addition, in a case where the measurement data is periodic data, frequency analysis processing and the like can be performed. Furthermore, the example in FIG. 9 illustrates that the frequency analysis processing is performed with respect to measurement data of “vibration A” as the “pre-processing”.

The “algorithm” is information that specifies an abnormality detection algorithm that is used in the diagnostic procedure. The example in FIG. 9 illustrates a case where “K averaging method” cluster analysis is used as the “algorithm”, and “cluster information”, which is used in cluster analysis as attached information, is stored in Datafile0. Furthermore, for example, the abnormality detection algorithm may be “main-component analysis” and the like.

The “post-processing” is information that specifies abnormality determination conditions which are used in determination of abnormality of the machine 1 after application of the abnormality detection algorithm, and the like. The example in FIG. 9 illustrates that as the “post-processing”, that is, as the abnormality determination conditions, the degree of abnormality of 3 or greater continues for three seconds or longer.

Furthermore, in the cluster analysis, n pieces of measurement data, which are designated by the “sensor”, are searched for predetermined time, and thus an n-dimensional vector space, in which the n pieces of measurement data are set as components, is assumed. In addition, cluster information is generated by using measurement data which is previously acquired in the n-dimensional vector space and includes n components in each time. That is, a plurality of the measurement data, which include the n components in each time, are divided into respective clusters in the n-dimensional vector space. In this embodiment, the cluster information (for example, Datafile0) is generated for each operation mode of the machine 1. The cluster information is information that defines a normal state of the machine.

In addition, in a case where measurement data, which does not pertain to any cluster, exists among the plurality of pieces of measurement data measured by the sensor 11, from the measurement data, it is regarded that abnormality occurs, that is, the abnormality or an abnormality symptom is shown in the machine 1.

In the cluster analysis, the “degree of abnormality” is defined as a Euclidean distance between a position at which measurement data at each time is shown and the center of a cluster that is closest to the position in the n-dimensional vector space. In this embodiment, with regard to the degree of abnormality, when the degree of abnormality of 3 or greater, which is obtained through “post-processing” calculation continues for three seconds or longer, it is regarded as the abnormality of the machine 1.

FIG. 17 is a view illustrating an example of calculation of the degree of abnormality using the cluster analysis. FIG. 17 illustrates an example in which division into two cluster is performed in a three-dimensional vector space by using three sensors including a sensor A (171), a sensor B (172), and a sensor C (173). A cluster 174 and a cluster 175 are generated by using data of a sensor A, data of a sensor B, and data of a sensor C among the plurality of sensor data 31 stored in the storage unit 30.

In calculation of the degree of abnormality, first, values of the sensor A, the sensor B, and the sensor C, which are measured in the three-dimensional vector space, are mapped as sensor data 176. Next, a distance between the sensor data 176 and the closest cluster (In FIG. 17, the cluster 174) is calculated. As the distance is longer, a difference with sensor data that was recorded in the past is greater. Therefore, a possibility of abnormality of the machine 1 becomes higher. In the example in FIG. 17, a distance with the closest cluster is set as the degree of abnormality.

Furthermore, the measurement data stated in this embodiment may be not only actual measurement data obtained by the sensor 11 (refer to FIG. 2) but also data obtained by pre-processing the actual measurement data. For example, in a case where frequency analysis “pre-processing” is performed with respect to arbitrary measurement data, time-series data of a power value (spectrum value) in each frequency band of the measurement data is also regarded as measurement data of a cluster analysis object. In addition, a power value of a frequency band that is an integral multiple of a rotation frequency of an electric motor may be used. For example, when the rotation frequency of the electric motor is 60 Hz, power values of 60 Hz, 120 Hz, 180 Hz, and 240 Hz are used. In addition, a power value in the vicinity of the integral multiple of the rotation frequency of the electric motor may be used. For example, when the rotation frequency of the electric motor is 60 Hz, the sum of power values from 55 Hz to 65 Hz, the sum of power values from 115 Hz to 125 Hz, the sum of power values from 175 Hz to 185 Hz, and the sum of power values from 235 Hz to 245 Hz are used.

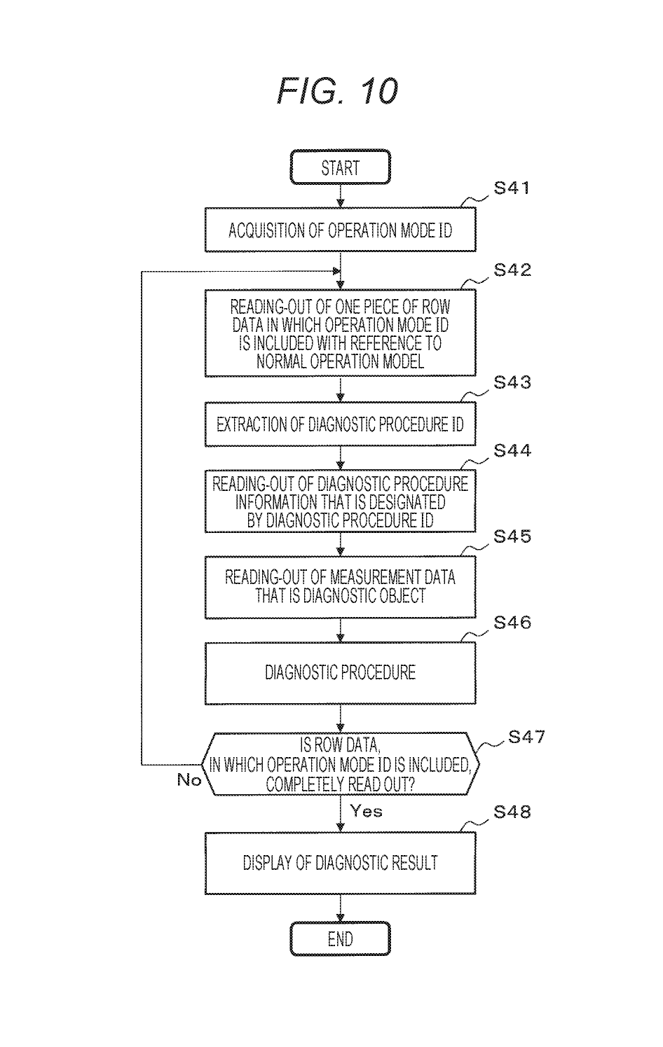

FIG. 10 is a flowchart illustrating an example of an abnormality diagnostic process that is executed by the abnormality diagnostic unit 23. Description will be made appropriately with reference to FIG. 2. As illustrated in FIG. 10, first, the abnormality diagnostic unit 23 acquires an operation mode ID that is supplied from the operation mode specifying unit 22 (step S41). For example, the abnormality diagnostic unit 23 acquires an operation mode ID “1” (activation operation mode: refer to FIG. 6(a)) that is supplied from the operation mode specifying unit 22.

Next, the abnormality diagnostic unit 23 selects one piece of row data in which the operation mode ID (failure mode ID acquired in step S41) is included in the “operation mode ID” column with reference to the normal operation model 33 stored in the storage unit 30 (step S42). In the example of FIG. 8, the abnormality diagnostic unit 23 selects and reads out one row among rows in which “1” is included in the “operation mode ID” column of the normal operation model 33. For example, the abnormality diagnostic unit 23 reads out data in the first row (data in which the failure mode is “bearing inner wheel damage”, and the diagnostic procedure ID is “1”).

Next, the abnormality diagnostic unit 23 extracts the diagnostic procedure ID that is included in the normal operation model that is read out (step S43). In the case of data in the first row of the normal operation model 33 in FIG. 8, as the diagnostic procedure ID, “1” is read out, and from the data in the first row, it can be seen that a diagnostic procedure designated by the diagnostic procedure ID “1” is a procedure of diagnosing absence or presence of the failure mode of “bearing inner wheel damage”.

Next, the abnormality diagnostic unit 23 reads out the diagnostic procedure information 34, which is designated by the diagnostic procedure ID, from the storage unit 30 (step S44), and reads out measurement data, which is a diagnostic object designated in the “sensor” column of the diagnostic procedure information 34, from the storage unit 30 (step S45). In the case of the example of the diagnostic procedure information 34 in FIG. 9, “vibration A” measurement data and “temperature” measurement data are read out from the sensor data 31.

Next, the abnormality diagnostic unit 23 executes “pre-processing”, “algorithm”, and “post-processing”, which are designated by the diagnostic procedure information 34, with respect to the read-out measurement data of a diagnostic object, to perform a diagnostic operation (step S46). For example, in the example of the diagnostic procedure in FIG. 9, the abnormality diagnostic unit 23 executes pre-processing of “frequency analysis” with respect to the measurement data of “vibration A”, and executes cluster analysis of “K averaging method” with respect to measurement data of “vibration A” and measurement data of “temperature”. In addition, posting-processing of detecting a case where the degree of abnormality of three or greater continues for three seconds or longer as “abnormality” on the basis of the result of the cluster analysis.

Next, the abnormality diagnostic unit 23 determines whether or not the row data, in which the failure mode ID (failure mode ID acquired in step S41) is included, is completely selected from the normal operation model 33 (step S47). Furthermore, the determination is an operation that is performed with respect to the processing result in in step S42. Therefore, in the determination in step S47, when it is determined that the row data, in which the failure mode ID is included, is not completely selected (No in step S47), the abnormality diagnostic unit 23 repeats again the subsequent processes from step S42.

On the other hand, in the determination in step S47, when it is determined that the row data, in which the failure mode ID is included, is completely selected (Yes in step S47), the abnormality diagnostic unit 23 displays a diagnostic result, which is obtained in the diagnostic process in step S46, on the display unit 42 (step S48).

### Learning Process

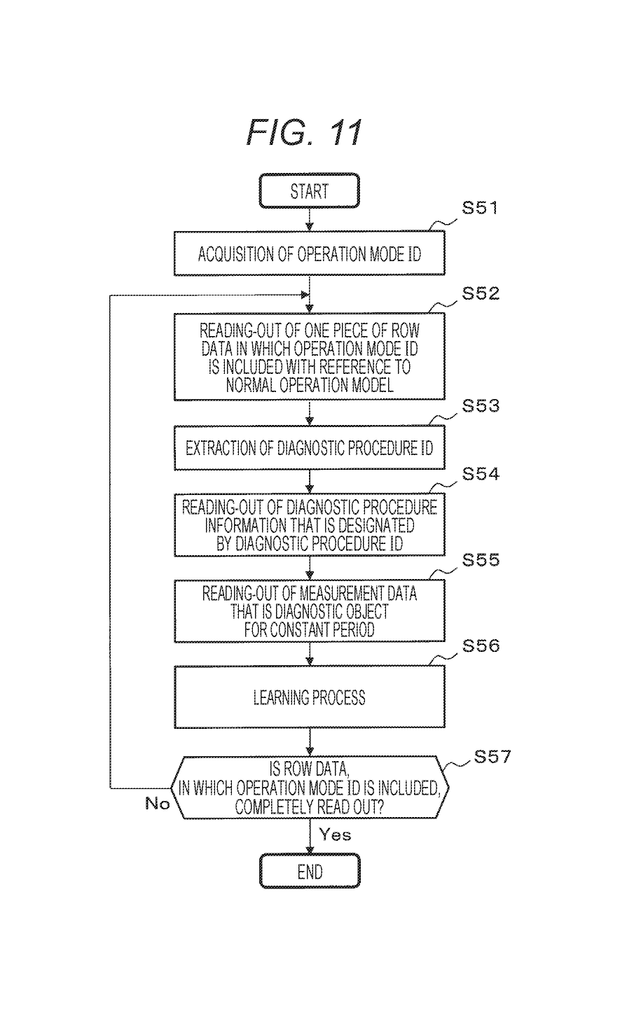

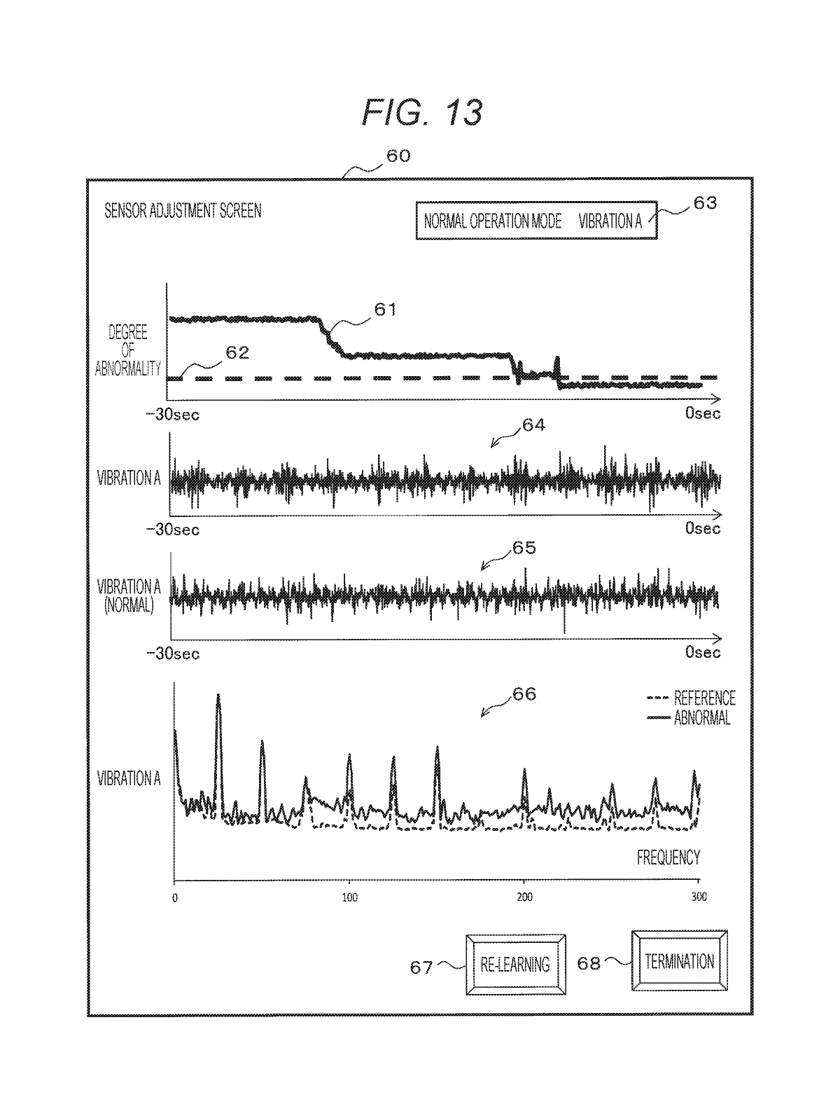

For example, when a command is given from the sensor adjusting unit 24 (specifically, re-learning button 67 in FIG. 13 is pressed), the learning unit 25 (refer to FIG. 2) calculates the normal operation model 33 by using the sensor data 31 and the diagnostic procedure information 34 in the storage unit 30. A learning process, which is executed by the learning unit 25, will be described in detail with reference to FIG. 11.

FIG. 11 is a flowchart illustrating an example of the learning process that is executed by the learning unit 25. As illustrated in FIG. 11, first, the learning unit 25 acquires an operation mode ID that is supplied from the operation mode specifying unit 22 (step S51). For example, the learning unit 25 acquires an operation mode ID “1” (activation operation mode: refer to FIG. 6(a)) that is supplied from the operation mode specifying unit 22.

Next, the learning unit 25 selects one piece of row data in which the operation mode ID (failure mode ID acquired in step S51 is included in the “operation mode ID” column with reference to the normal operation model 33 (step S52). In the example in FIG. 11, the learning unit 25 selects and reads out one row among rows in which “1” is included in the “operation mode ID” column of the normal operation model 33. For example, the learning unit 25 reads out data in the first row (data in which the failure mode is “bearing inner wheel damage”, and the diagnostic procedure ID is “1”).

Next, the learning unit 25 extracts the diagnostic procedure ID that is included in the normal operation model that is read out (step S53). In the case of data in the first row of the normal operation model 33 in FIG. 11, as the diagnostic procedure ID, “1” is read out, and it can be seen that from the data in the first row, a diagnostic procedure designated by the diagnostic procedure ID “1” is a procedure of diagnosing absence or presence of the failure mode of “bearing inner wheel damage”.

Next, the learning unit 25 reads out the diagnostic procedure information 34, which is designated by the diagnostic procedure ID, from the diagnostic procedure information 34 (step S54), and reads out measurement data, which is a diagnostic object designated in the “sensor” column of the diagnostic procedure information 34, from the sensor data 31 for a constant period (step S55). In the case of the example of the diagnostic procedure information 34 in FIG. 9, measurement data of “vibration A” and measurement data of “temperature”, which correspond to one day, are read out from the sensor data 31.

Next, the learning unit 25 executes the learning process (mechanical learning process) by performing “pre-processing” and “algorithm”, which are designated by the diagnostic procedure information 34, with respect to the read-out measurement data of a diagnostic object to calculate a normal operation model (step S56). For example, in the example of the diagnostic procedure in FIG. 9, the learning unit 25 gives a processing command to the abnormality diagnostic unit 23 to execute pre-processing of “frequency analysis” with respect to the measurement data of “vibration A”, and obtains a processing result of “K averaging method” cluster analysis with respect to the measurement data of “vibration A” and the measurement data of “temperature”.

Next, the learning unit 25 determines whether or not the row data, in which the failure mode ID (the failure mode ID acquired in step S51) is included, is completely selected from the normal operation model 33 (step S57). Furthermore, the determination is a process that is performed with respect to the processing result in in step S52. Therefore, in the determination in step S57, when it is determined that the row data, in which the failure mode ID is included, is not completely selected (No in step S57), the learning unit 25 repeats again the processes from step S52. From the determination in step S57, in a case where the row data, in which the failure mode ID is included, is completely selected (Yes in step S57), the process is terminated.

### Sensor Adjusting Process

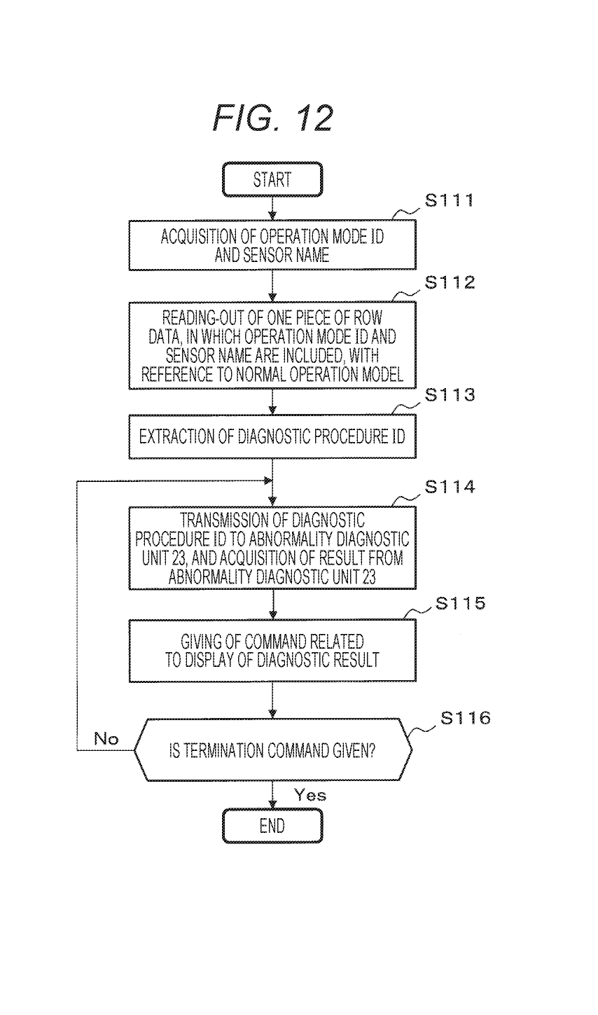

When an instruction indicating execution of a sensor adjustment mode is input from the input unit 41 after maintenance by the maintenance person 3, the sensor adjusting unit 24 operates. The sensor adjusting process, which is executed by the sensor adjusting unit 24, will be described in detail with reference to FIG. 12. Description will be made appropriately with reference to FIG. 2.

When a command related to a sensor adjustment mode is given from the input unit 41, the sensor adjusting unit 24 gives a command for the abnormality diagnostic unit 23 to perform a diagnostic process by using the sensor data 31, the diagnostic procedure ID of the normal operation model 33, and the diagnostic procedure information 34 corresponding to the diagnostic procedure ID which are stored in the storage unit 30. The sensor adjusting unit 24 receives a result from the abnormality diagnostic unit 23, and gives a display command to the display unit 42. As illustrated in FIG. 12, when an operation mode ID and a sensor name that is an adjustment object are input from the input unit 41 by the maintenance person 3, the sensor adjusting unit 24 acquires the operation mode ID and the sensor name (step S111). Specifically, the maintenance person 3 may select a sensor that is an adjustment object from a sensor list or freely input the sensor for designation. For example, the maintenance person 3 inputs an operation mode ID “1” (normal operation mode: refer to FIG. 6(b)) and sensor “vibration A” through the input unit 41.

Next, the sensor adjusting unit 24 selects one piece of row data in which the operation mode ID (failure mode ID acquired in step S111) is included in the “operation mode ID” column with reference to the normal operation model 33 stored in the storage unit 30 (step S112). In the example of FIG. 12, the sensor adjusting unit 24 selects and reads out one row among rows in which “1” is included in the “operation mode ID” column of the normal operation model 33. For example, the sensor adjusting unit 24 reads out data in the first row (data in which the failure mode is “bearing inner wheel damage”, and the diagnostic procedure ID is “1”).

Next, the sensor adjusting unit 24 extracts the diagnostic procedure ID that is included in the normal operation model that is read out (step S113). In the case of data in the first row of the normal operation model 33 in FIG. 12, as the diagnostic procedure ID, “1” is read out, and it can be seen that from the data in the first row, a diagnostic procedure designated by the diagnostic procedure ID “1” is a procedure of diagnosing absence or presence of the failure mode of “bearing inner wheel damage”.

Next, the sensor adjusting unit 24 supplies (transmits) the diagnostic procedure ID to the abnormality diagnostic unit 23 to give a command related to abnormality diagnosis by using sensor data in acquisition, and obtains an abnormality diagnostic result from the abnormality diagnostic unit 23 (step S114). Next, after receiving the diagnostic result from the abnormality diagnostic unit 23, the sensor adjusting unit 24 gives a command for the display unit 42 to display the result (step S115). Next, the sensor adjusting unit 24 determines whether or not a termination instruction is given from the input unit 41 (step S116). In the determination in step S116, when it is determined that the termination command is not given (No in step S116), the sensor adjusting unit 24 repeats again the processes from step S114. In the determination in step S116, when it is determined that the termination command is given (Yes in step S116), the sensor adjustment mode is terminated. The maintenance person 3 performs sensor attachment while referencing to the diagnostic result displayed on the display unit 42 in step S115.

FIG. 13 is a view illustrating an example of a sensor adjustment screen 60 of the sensor adjusting unit 24. Description will be made appropriately with reference to FIG. 2. When the sensor adjusting unit 24 gives a command for diagnostic result display (step S115 in FIG. 12), the degree of abnormality of real-time sensor data is displayed on the display unit 42 in a time-series manner. Furthermore, in the example in FIG. 13, for example, a graph 61 of the time-series data of the degree of abnormality before 30 seconds from current time is illustrated, and the time-series data is periodically updated, and thus it is possible to always confirm a new degree of abnormality.

The maintenance person 3 confirms reproducibility of a sensor state before maintenance while confirming the sensor adjustment screen 60. A threshold value 62 is the upper limit of the degree of abnormality that is set in advance and is required for re-attachment of the sensor 11. Within the threshold value, the reproducibility of the sensor is secured and thus the sensor adjustment operation is terminated. A window 63 represents an operation mode and a sensor name that is an adjustment object. In a case where a plurality of diagnostic procedure IDs exist, a plurality of the graphs 61 are displayed (not illustrated in FIG. 13).

A graph 64 and a graph 65 are graphs which simultaneously show time-series data of sensor data of an adjustment object before 30 seconds from current time and time-series data of sensor data of the normal operation model. Each time-series data is periodically updated, and thus it is possible to always confirm a new degree of abnormality. Here, real-time time-series data of “vibration A” and time-series data of the normal operation model in the object sensor are illustrated.

In addition, in a case where pre-processing is included in the diagnostic procedure (frequency analysis in the diagnostic procedure ID “1” in FIG. 9), a pre-processing result is displayed on a graph 66. The graph is updated at a constant interval. In the case of the graph 66, the horizontal axis represents a frequency. The graph 66 also simultaneously displays a frequency analysis result of the normal operation model, and a frequency analysis result of real-time sensor data.

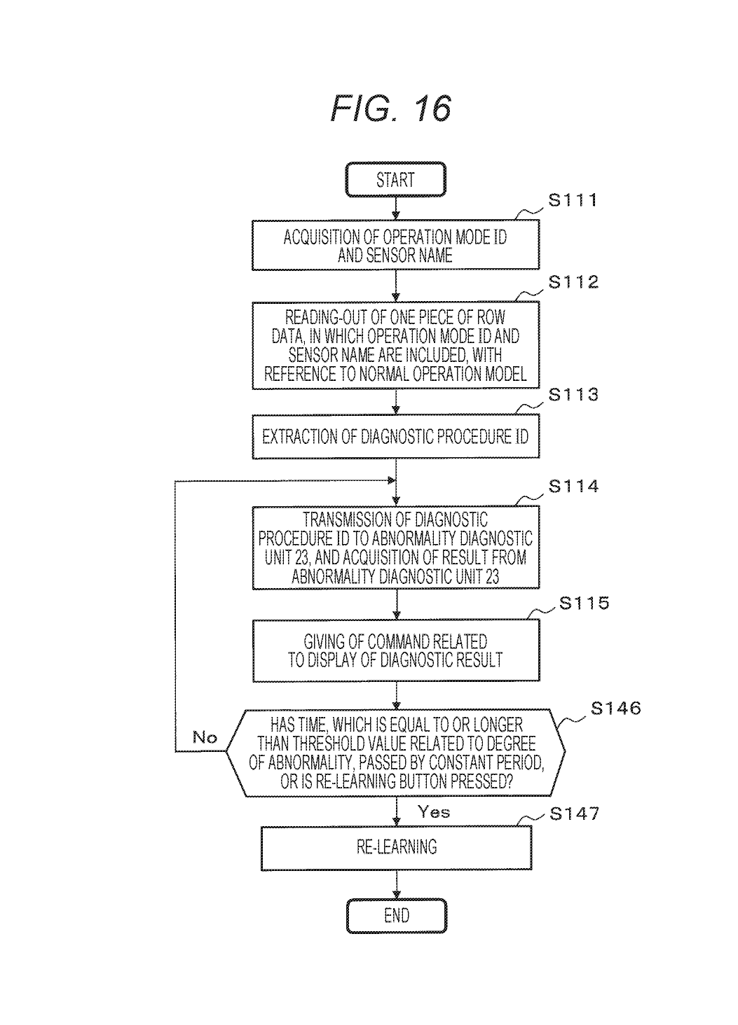

The maintenance person 3 performs a sensor attaching operation while referencing to the graphs 61, 64, and 66, and the threshold value 62. When determining that the sensor attachment is completed, the maintenance person 3 presses a termination button 68. When the termination button 68 is pressed, the sensor adjustment screen 60 is closed. Furthermore, a re-learning button 67 will be described later with reference to FIG. 16.

According to the machine diagnostic device 2 of this embodiment, it is possible to easily assist the maintenance person 3 with sensor attachment adjustment so that abnormality sensing performance can be maintained even after maintenance of the machine 1.

### Embodiment 2

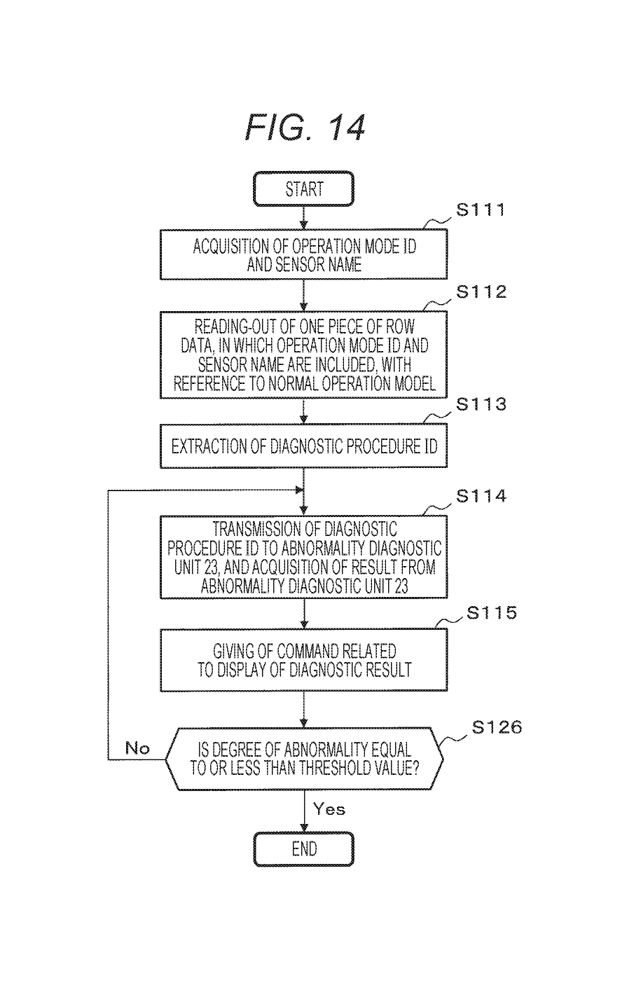

FIG. 14 is a flowchart illustrating an adjusting process of the sensor adjusting unit 24 according to Embodiment 2. In a case where the termination command is given from the maintenance person 3, the sensor adjusting unit 24 according to Embodiment 1 terminates a process, but there is no limitation thereto. In Embodiment 2, when the degree of abnormality is equal to or less than a threshold value set in advance during sensor adjustment, the sensor adjusting unit 24 automatically terminates a process. A processing flow of the sensor adjusting unit 24 will be described with reference to FIG. 14. In FIG. 14, the same reference numeral will be given to the same step as in FIG. 12, and description thereof will not be repeated.

In step S126, the sensor adjusting unit 24 determines whether or not the degree of abnormality (error) becomes equal to or less than a threshold value (first threshold value) that is set in advance. When the degree of abnormality becomes equal to or less than the threshold value (Yes in step S126), the sensor adjusting unit 24 terminates the sensor adjusting process. In a case where the degree of abnormality is greater than the threshold value (No in step S126), the sensor adjusting unit 24 determines that the sensor adjustment is necessary still, and the process returns to step S114.

In Embodiment 2, when the sensor adjusting process is terminated and the sensor adjustment screen 60 is turned off, the maintenance person 3 can immediately grasp a situation in which the sensor adjustment is terminated.

### Embodiment 3

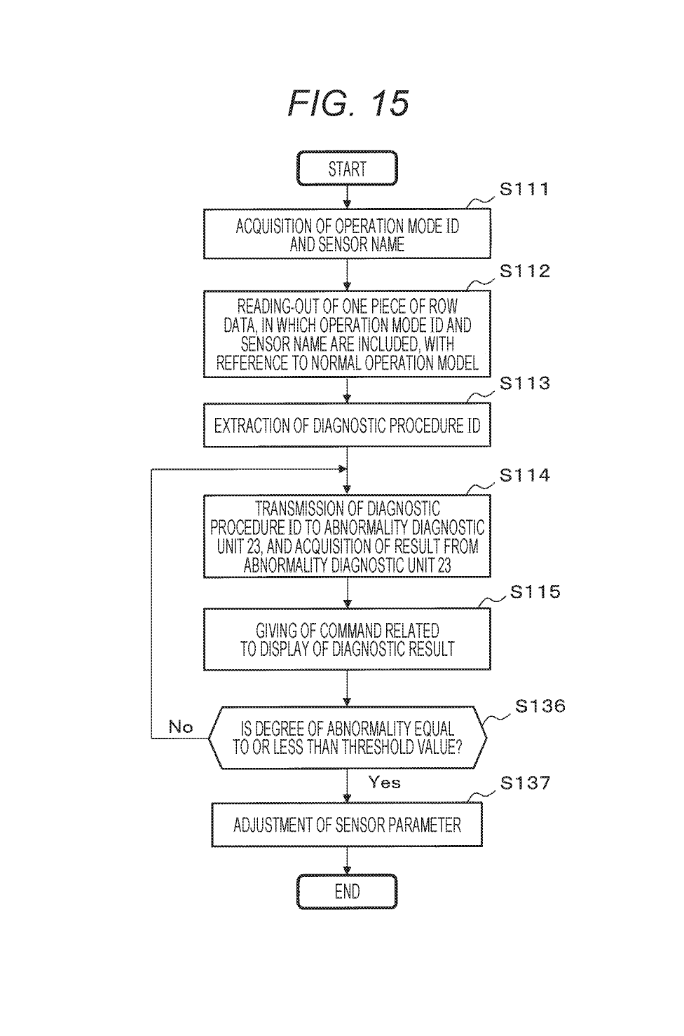

FIG. 15 is a flowchart illustrating an adjusting process of the sensor adjusting unit 24 according to Embodiment 3. In Embodiment 3, when an abnormality value becomes equal to or less than a constant value in the sensor adjustment mode, the sensor adjusting unit 24 automatically adjusts a sensor parameter 35 stored in the storage unit 30. A processing flow of the sensor adjusting unit 24 will be described with reference to FIG. 15. In FIG. 15, the same reference numeral will be given to the same step as in FIG. 12, and description thereof will not be repeated.

In step S136, the sensor adjusting unit 24 determines whether or not the degree of abnormality (error) becomes equal to or less than a threshold value (first threshold value) that is set in advance. When the degree of abnormality becomes equal to or less than the threshold value (Yes in step S136), with regard to parameters (a correction value and an offset) of an object sensor, the sensor adjusting unit 24 automatically adjusts the parameters so that the degree of abnormality becomes equal to or less than a second threshold value smaller than the first threshold value (step S137), and terminates the process. In a case where the degree of abnormality is greater than the threshold value (No in step S136), the sensor adjusting unit 24 determines that the sensor adjustment is necessary still, and the process returns to step S114.

In Embodiment 3, rough sensor attachment is executed by the maintenance person 3, and minute final adjustment is executed by the sensor adjusting unit 24 in step S137. According to this, it is possible to shorten adjustment time, which is necessary for the maintenance person 3, of the sensor 11.

### Embodiment 4

FIG. 16 is a flowchart illustrating an adjusting process of the sensor adjusting unit 24 according to Embodiment 4. In Embodiment 4, when time, which is equal to or longer than a threshold value (first threshold value) relating to the degree of abnormality, has passed by predetermined time (constant time) in the sensor attaching operation, or when the re-learning button 67 (refer to FIG. 13) is pressed, it is determined that reproduction to a state before maintenance is impossible in the sensor attaching operation, and normal data is reconstructed. A processing flow of Embodiment 3 will be described with reference to FIG. 16. In FIG. 16, the same reference numeral will be given to the same step as in FIG. 12, and description thereof will not be repeated.

In step S146, the sensor adjusting unit 24 determines whether or not time, which is set in advance with respect to the degree of abnormality and is equal to or longer than a threshold value (first threshold value), has passed by constant time, or the re-learning button 67 is pressed. When the time, which is equal to or longer than the threshold value set in advance with respect to the degree of abnormality, has passed by constant time, or the re-learning button 67 is pressed (Yes in step S146), the sensor adjusting unit 24 proceeds to step S147. When the time, which is equal to or longer than the threshold value set in advance with respect to the degree of abnormality, has not passed by constant time, or the re-learning button 67 is not pressed (No in step S146), the process returns to step S114.

Next, in step S147, the sensor adjusting unit 24 provides the operation mode ID and the sensor name, which are input to the abnormality diagnostic unit 23 in step S111, to the learning unit 25, and gives a command for the learning unit 25 to learn again the normal operation model. The re-learning command in step S147 is executed when the button 67 (refer to FIG. 13) is pressed.

As described above, according to the machine diagnostic device 2 according to this embodiment, the maintenance person 3 can adjust the sensor attaching operation while recognizing a difference from a normal operation model in the past before maintenance. Accordingly, it is possible to provide a machine diagnostic device and a machine diagnostic method which are applicable to a machine after maintenance.

### REFERENCE SIGNS LIST

1 machine

2 machine diagnostic device

3 maintenance person

4 manager

11 sensor

21 sensor data acquiring unit

22 operation mode specifying unit

23 abnormality diagnostic unit

24 sensor adjusting unit

25 learning unit

30 storage unit

31 sensor data

32 operation mode data

33 normal operation model

34 diagnostic procedure information

35 sensor parameter

41 input unit

42 display unit

60 sensor adjustment screen

62 degree of abnormality (error)

1. A machine diagnostic device, comprising:
a sensor data acquiring unit that acquires time-series sensor data that is measured by a sensor attached to a machine having one or more operation modes;
a learning unit that calculates a normal operation model through statistical processing of the sensor data before detachment of the sensor;
an abnormality diagnostic unit that diagnoses abnormality of the machine on the basis of the sensor data and the normal operation model; and
a sensor adjusting unit that displays an error between a normal operation model before detachment of the sensor and sensor data after attachment of the sensor on a display unit as a sensor adjustment mode when the sensor is attached again to the machine after detachment of the sensor.

2. The machine diagnostic device according to claim 1,
wherein when the error becomes equal to or less than a first threshold value, the sensor adjusting unit terminates the sensor adjustment mode.

3. The machine diagnostic device according to claim 1,
wherein when the error becomes equal to or less than a first threshold value, the sensor adjusting unit adjusts a correction value and an offset value of the sensor, which are used in the sensor data acquiring unit, to be equal to or less than a second threshold value that is smaller than the first threshold value.

4. The machine diagnostic device according to claim 1,
wherein in a case where the error is equal to or greater than a first threshold value even after passage of predetermined time, or a command is given from an input unit, the sensor adjusting unit gives a command for the learning unit to recalculate the normal operation model.

5. The machine diagnostic device according to claim 1, further comprising:
an operation mode specifying unit that specifies an operation mode from the sensor data that is acquired,
wherein the learning unit calculates the normal operation model for each of the operation modes through statistical processing of the sensor data before detachment of the sensor,
the abnormality diagnostic unit diagnoses abnormality of the machine for each of the operation modes on the basis of the sensor data and the normal operation model, and
when the sensor is attached again to the machine after detachment of the sensor, the sensor adjusting unit displays an error between a normal operation model before detachment of the sensor and sensor data after attachment of the sensor on a display unit for each of the operation modes.

6. The machine diagnostic device according to claim 1,
wherein the error is a distance between a center of a cluster based on the sensor data before detachment of the sensor, and sensor data after attachment of the sensor.

7. A machine diagnostic method that allows an abnormality diagnostic device that diagnoses abnormality of a machine to perform,
a sensor data acquiring process of acquiring time-series sensor data that is measured by a sensor attached to the machine having one or more operation modes;
a learning process of calculating a normal operation model through statistical processing of the sensor data before detachment of the sensor;
an abnormality diagnostic process of diagnosing abnormality of the machine on the basis of the sensor data and the normal operation model; and
a sensor adjusting process of displaying an error between a normal operation model before detachment of the sensor and sensor data after attachment of the sensor on a display unit as a sensor adjustment mode when the sensor is attached again to the machine after detachment of the sensor.

8. The machine diagnostic method according to claim 7,
wherein in the sensor adjusting process, when the error becomes equal to or less than a first threshold value, the sensor adjustment mode is terminated.

9. The machine diagnostic method according to claim 7,
wherein in the sensor adjusting process, when the error becomes equal to or less than a first threshold value, a correction value and an offset value of the sensor, which are used in the sensor data acquiring unit, are adjusted to be equal to or less than a second threshold value that is smaller than the first threshold value.

10. The machine diagnostic method according to claim 7,
wherein in the sensor adjusting process, in a case where the error is equal to or greater than a first threshold value even after passage of predetermined time, or a command is given from an input unit, a command is given for the learning unit to recalculate the normal operation model.

11. The machine diagnostic method according to claim 7, wherein the machine diagnostic device is allowed to further execute:
an operation mode specifying process of specifying an operation mode from the sensor data that is acquired,
in the learning process, the normal operation model for each of the operation modes is calculated through statistical processing of the sensor data before detachment of the sensor,
in the abnormality diagnostic process, abnormality of the machine for each of the operation modes is diagnosed on the basis of the sensor data and the normal operation model, and
in the sensor adjusting process, when the sensor is attached again to the machine after detachment of the sensor, an error between a normal operation model before detachment of the sensor and sensor data after attachment of the sensor is displayed on a display unit for each of the operation modes.

12. The machine diagnostic method according to claim 7,
wherein the error is a distance between a center of a cluster based on the sensor data before detachment of the sensor, and sensor data after attachment of the sensor.
